(19) United States
(12) Patent Application Publication
(10) Pub. No.: US 2006/0028097 A1
(43) Pub. Date: Feb. 9, 2006

(54) Piezoelectric loudspeaker

(76) Inventors: Norikazu Sashida, Gunma (JP); Shigeo Ishii, Gunma (JP); Hiroshi Hamada, Gunma (JP); Yoshiyuki Watanabe, Gunma (JP)

Correspondence Address: KNOBBE MARTENS OLSON & BEAR LLP, 2040 MAIN STREET, FOURTEENTH FLOOR, IRVINE, CA, 92614, US

(21) Appl. No.: 11/154,149

(22) Filed: Jun. 16, 2005

(30) Foreign Application Priority Data
Jun. 18, 2004 (JP) 2004-181815
Jun. 18, 2004 (JP) 2004-181816

(51) Int. Cl. H01L 41/083

(52) U.S. Cl. 310/328

(57) ABSTRACT

A piezoelectric loudspeaker includes a diaphragm and a piezoelectric element bonded on a principal surface of the diaphragm. An electrode layer is provided on the surface of the piezoelectric element. The piezoelectric element has a structure formed by alternately laminating at least three piezoelectric layers and electrode layers in order to achieve a sufficient driving force. A conductive path composed of a strip-shaped metal foil and having an adhesive layer on the reverse face thereof is provided on the surface of the electrode layer. The adhesive layer may be conductive or nonconductive. Conductive paste having a low rigidity and a low volume resistivity is applied so as to be disposed over the surfaces of the conductive path and the electrode layer. Thus, a conductive layer having a Young's modulus of 100 MPa or less and a volume resistivity of 6×10⁻³ Ωcm or less is provided.

### BACKGROUND OF THE INVENTION

1. Field of the Invention

The present invention relates to a piezoelectric loudspeaker, and more specifically, to improvements of power loss, the decrease in sound pressure, and the reproducibility of sounds in a thin piezoelectric loudspeaker.

2. Description of the Related Art

For example, in a known ultra-thin piezoelectric loudspeaker having a thickness of 1 mm or less, at least one piezoelectric element (piezoelectric sheet) that is polarized in the thickness direction of the sheet is bonded on at least one surface of a metal diaphragm. In order to achieve a sufficient sound pressure, the piezoelectric element must be a layered product formed by laminating piezoelectric layers composed of a piezoelectric material and electrode layers. In such a layered product, since the electrode must be sintered at the same time, a silver-palladium alloy is used as the electrode material that can withstand the sintering process. For example, as disclosed in Japanese Unexamined Patent Application Publication No. 2003-078995, a metal foil having a conductive adhesive thereon and having a thickness of 0.1 mm or less is used as a conductive path that applies signals to the electrode disposed on the surface of the piezoelectric material. This structure provides a thin loudspeaker overall. In addition, decreasing the palladium ratio in the electrode is effective in order to decrease the cost. Accordingly, a piezoelectric material that is sintered at a relatively low temperature is used and, for example, a material wherein the ratio of silver to palladium is about 9:1 is used as the electrode. However, the shrinkage of such an electrode including a small amount of palladium proceeds at a temperature lower than the shrinkage temperature of the piezoelectric material, i.e., a base material. As a result, a stress generated by mismatched shrinkages during sintering may deform or break the piezoelectric element. In order to solve this problem, the same piezoelectric material as the base material is added to the electrode so as to match the shrinkage ratio of the base material and that of the electrode.

However, the above piezoelectric material added to the electrode is eliminated from the metals during sintering. Consequently, particles of the piezoelectric material are precipitated on the surface of an outer electrode of the piezoelectric element. Since the piezoelectric material is a nonconductor, the precipitated particles increase the contact resistance. As a result, the electric power consumed at the contact part is increased. This phenomenon decreases energy that is effectively converted to sounds, thereby decreasing the conversion efficiency. In order to prevent this problem, the area of the conductive path (i.e., metal foil) is increased so as to decrease the contact resistance. However, according to this method, the conductive path impedes the vibration of the diaphragm. In such a case, the resonant frequency becomes high and the sound pressure is decreased. Furthermore, when an electrical contact is provided using the conductive adhesive, the piezoelectric material itself, which is a nonconductor, becomes a barrier. Consequently, the contact between the conductive adhesive and the electrode becomes unstable. In such a case, the contact resistance is changed with the vibration and the reproducibility of sounds is significantly impaired.

### SUMMARY OF THE INVENTION

In view of the above situation, it is an object of the present invention to provide a thin piezoelectric loudspeaker in which the contact resistance is decreased without impairing the sound quality and the power loss can be decreased. It is another object of the present invention to provide a thin piezoelectric loudspeaker in which a stable electrical connection is formed so as to provide an excellent sound reproducibility.

In order to achieve the above objects, according to an aspect of the present invention, a piezoelectric loudspeaker includes a piezoelectric element including a piezoelectric material and an electrode layer that is provided on at least one principal surface of the piezoelectric element; a diaphragm applied on the other principal surface of the piezoelectric element; a conductive path composed of a strip-shaped metal foil conductively connecting electrode layers of the piezoelectric element to each other or connecting one of the electrode layers of the piezoelectric element to an external circuit, the conductive path being bonded on the electrode layer by an adhesive layer provided on the reverse face thereof; and a conductive layer formed by applying conductive paste, the conductive layer being provided over the surface of the electrode layer and the top face of the conductive path, and the conductive layer having a Young's modulus of 100 MPa or less and a volume resistivity of 6×10⁻³ Ωcm or less.

According to the piezoelectric loudspeaker, each of the contact area of the surface of the electrode layer with the conductive layer and the contact area of the conductive path with the conductive layer is preferably at least 0.8 mm² and the thickness of the conductive layer is preferably at least 0.01 mm. The contact area of the surface of the electrode layer with the conductive layer is preferably 20 mm² or less. The diaphragm preferably has a diameter of 10 to 50 mm.

Furthermore, the piezoelectric element is preferably applied on at least one principal surface of the diaphragm. The piezoelectric element preferably has a layered structure formed by alternately laminating a plurality of piezoelectric layers and electrode layers. The piezoelectric element preferably includes at least three piezoelectric layers.

According to another aspect of the present invention, a piezoelectric loudspeaker includes a piezoelectric element including a piezoelectric material and an electrode layer that is provided on at least one principal surface of the piezoelectric element; a diaphragm applied on the other principal surface of the piezoelectric element; a conductive path composed of a strip-shaped metal foil conductively bonded on the electrode layer in order to connect electrode layers of the piezoelectric element to each other or connect one of the electrode layers of the piezoelectric element to an external circuit conductively; a conductive adhesive layer provided on the reverse face of the conductive path; and a conductive layer formed by applying conductive paste, the conductive layer being provided over the surface of the electrode layer and the top face of the conductive path. In the piezoelectric loudspeaker, the conductive layer is provided so as to be connected to the electrode layer at a plurality of points along the edge of the conductive path. The conductive layer is preferably provided on both sides of the conductive path or across the conductive path. The conductive layer preferably has a Young's modulus of 100 MPa or less and a volume resistivity of 6×10⁻³ Ωcm or less.

According to the piezoelectric loudspeaker, each of the contact area of the surface of the electrode layer with the conductive layer and the contact area of the conductive path with the conductive layer is preferably at least 0.8 mm² and the thickness of the conductive layer is preferably at least 0.01 mm. The contact area of the surface of the electrode layer with the conductive layer is preferably 20 mm² or less. The diaphragm preferably has a diameter of 10 to 50 mm.

Furthermore, the piezoelectric element is preferably applied on at least one principal surface of the diaphragm. The piezoelectric element preferably has a layered structure formed by alternately laminating a plurality of piezoelectric layers and electrode layers. The piezoelectric element preferably includes at least three piezoelectric layers.

The above and other objects, features and advantages of the present invention will become apparent from the following detailed description taken with the accompanying drawings.

### BRIEF DESCRIPTION OF THE DRAWINGS

FIG. 1A is a plan view of a piezoelectric loudspeaker according to a first embodiment of the present invention.

FIG. 1B is a perspective view of the first embodiment.

FIG. 1C is a perspective view showing the reverse face of a conductive path of the first embodiment.

FIG. 1D is a plan view showing a modification of the first embodiment.

FIG. 1E is a plan view showing another modification of the first embodiment.

FIG. 2 is a main cross-sectional view of a piezoelectric loudspeaker according to Examples of the present invention.

### DESCRIPTION OF THE PREFERRED EMBODIMENTS

The present invention can provide numerous physical embodiments, depending upon the environment and requirements of use. Substantial numbers of the embodiments shown and described herein have been made, tested, and used, and all have performed in a highly satisfactory manner.

### First Embodiment

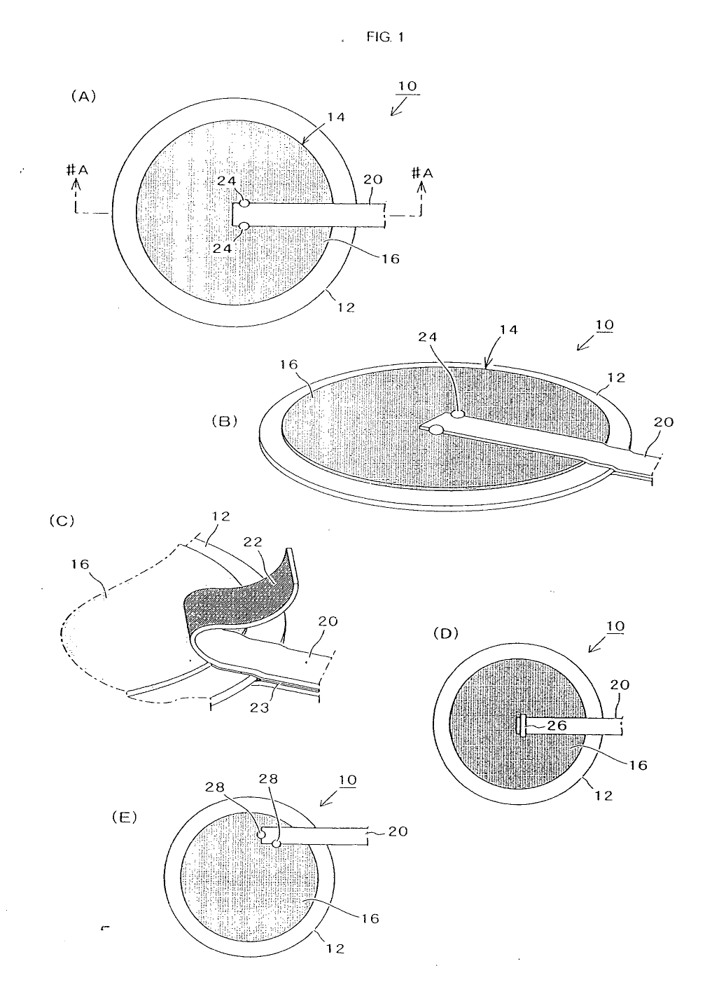

The best embodiment for carrying out the present invention will now be described in detail with reference to Examples. FIGS. 1A to 1E are views showing the fundamental structure of a piezoelectric loudspeaker of the present invention. FIG. 1A is a plan view of a first embodiment, FIG. 1B is a perspective view thereof, FIG. 1C is a perspective view showing the reverse face of a conductive path, FIG. 1D is a plan view showing a modification of the first embodiment, and FIG. 1E is a plan view showing another modification of the first embodiment.

Referring to FIG. 1, a piezoelectric loudspeaker 10 of the present invention includes a metal diaphragm 12 and a piezoelectric element 14 applied on the diaphragm 12. The piezoelectric element 14 is a layered product including piezoelectric layers. An electrode layer 16 is provided on at least one principal surface of the layered product. The piezoelectric loudspeaker 10 may be a unimorph type in which the piezoelectric element 14 is provided on one of the principal surfaces of the diaphragm 12. Alternatively, the piezoelectric loudspeaker 10 may be a bimorph type in which two piezoelectric elements 14 are provided on both faces of the diaphragm 12. The diaphragm 12 has a thickness of, for example, 0.1 mm or less in order that the total thickness of the piezoelectric loudspeaker 10 is 1 mm or less. Furthermore, in order to achieve a sufficient driving force, the piezoelectric element 14 has a layered structure in which at least three piezoelectric layers and electrode layers are alternately laminated and the total thickness of the piezoelectric element 14 is 0.1 mm or less.

Examples of the material of electrode layers 16 disposed between the piezoelectric layers and on the top and reverse faces of the piezoelectric element 14 include an alloy of silver and palladium (silver/palladium=9/1 to 10/0 (molar ratio)) and silver. The electrode layers 16 are formed as follows. An alloy (or silver) powder, a piezoelectric material powder, and a binder are added to an appropriate solvent to prepare paste. The paste is then applied on green sheets composed of a piezoelectric material by, for example, screen printing. Subsequently, a strip-shaped metal foil having a thickness of 0.1 mm or less and having an adhesive layer 22 on the reverse face thereof is prepared. The metal foil is applied on the electrode layer 16 disposed on the surface of the piezoelectric element 14. The metal foil forms a conductive path 20 connecting the electrode layers 16 to each other or connecting the outer electrode layer 16 to an external circuit. In the present embodiment, the adhesive layer 22 is electrically conductive. Therefore, in order to prevent short-circuiting between the conductive adhesive layer 22 and the diaphragm 12, an appropriate measure for insulation must be taken. For example, as shown in FIG. 1C, an insulating tape 23 is applied on a part where the adhesive layer 22 is in contact with the diaphragm 12. Although the conductive adhesive layer 22 is used in this embodiment, a nonconductive adhesive may be used. In such a case, the insulating tape 23 is not required.

Subsequently, conductive paste having a low rigidity and a low volume resistivity is applied so as to be disposed over the surfaces of the conductive path 20 and the electrode layer 16. Thus, a conductive layer is formed. Regarding the application shape of the conductive paste, the conductive paste may be applied so as to be connected to the electrode layer 16 at a plurality of points along the edge of the conductive path 20. Preferably, the conductive paste is applied on both sides of the conductive path 20 or applied across the conductive path 20. For example, as shown in the piezoelectric loudspeaker 10 in FIG. 1A, two circular conductive layers 24 are formed. Alternatively, as shown in FIG. 1D, a rectangular conductive layer 26 is also preferable. As shown in the piezoelectric loudspeaker 10 in FIG. 1E, when the conductive path 20 is disposed near the edge of the piezoelectric element 14, unlike the examples shown in FIGS. 1A and 1D, conductive layers cannot be applied on both sides of the conductive path 20. In such a case, circular conductive layers 28 may be applied on one side and the leading end of the conductive path 20.

Conductive paste having a low rigidity and a low volume resistivity is used as the conductive layer 24, 26, or 28. More specifically, conductive paste having a Young's modulus of 100 MPa or less and a volume resistivity of 6×10⁻³ Ωcm or less is preferably used. When the Young's modulus exceeds the above value, the conductive paste is broken because the paste cannot withstand the stress caused by the deformation of the diaphragm 12. Furthermore, in such a case, since the conductive paste acts as a resistance against the displacement of the diaphragm 12, the sound quality is impaired. Table 1 shows an example of the relationship between the Young's modulus of the conductive paste used as the conductive layer and the occurrence of breaking caused by driving the piezoelectric loudspeaker 10. Paste A is polyester-based paste, Paste B is silicone-based paste, Paste C is epoxy-based paste, and Paste D is polyimide-based paste. All types of the paste include silver as conductive filler.

TABLE 1

| | Young's | Volume | | | |
|---|---|---|---|---|---|
| | modulus | resistivity | | | |
| Paste | (MPa) | (Ω cm) | Filler | Resin | Breaking |
| A | 60 | 1 × 10⁻³ | Silver | Polyester base | Not broken |
| B | 600 | 1 × 10⁻⁶ | Silver | Silicone base | Broken |
| C | 1,000 | 1 × 10⁻³ | Silver | Epoxy base | Broken |
| D | 1,400 | 1 × 10⁻⁵ | Silver | Polyimide base | Broken |

As is apparent from Table 1, although Paste B to Paste D satisfy the condition of the volume resistivity of 6×10⁻³ Ωcm or less, the rigidity is excessively high. As a result, the paste is broken by driving the piezoelectric loudspeaker.

Table 2 shows the change in sound pressure when the Young's modulus of conductive paste is changes, In this example, the conductive layer 26 having a shape shown in FIG. 1D is formed with conductive paste.

TABLE 2

| | Deterioration of sound |
|---|---|
| Young's modulus | pressure |
| (MPa) | (dB) |
| 0 | 0.00 |
| (Without conductive paste) | |
| 50 | −0.05 |
| 100 | −0.10 |
| 200 | −0.22 |
| 500 | −0.43 |
| 1,000 | −0.61 |
| 2,000 | −0.93 |
| 5,000 | −1.49 |

As is apparent from the results in Table 2, in order to suppress the deterioration of sound pressure within, for example, 0.1 dB, the upper limit of the Young's modulus of the conductive paste is 100 MPa. Accordingly, in order to prevent the breaking by driving and to minimize the deterioration of sound quality, the Young's modulus of the conductive paste is preferably 100 MPa or less.

When the volume resistivity exceeds 6×10^{31 3} Ωcm, the contact resistance cannot be described sufficiently. As described above, the application shape of the conductive paste may be any shape such as a circular shape or a rectangular shape so long as the conductive paste is connected to the electrode layer 16 at a plurality of points along the edge of the conductive path 20. However, each of the area of the conductive paste overlapping with the conductive path 20 and the area of the conducting paste overlapping with the electrode layer 16 has an area of at least 0.8 mm². When the area is smaller than 0.8 mm², the resistance at the conductive paste portion (conductive layer 24, 26, or 28) is not sufficiently decreased and a stable contact state cannot be achieved. Table 3 shows the deterioration of sound pressure when the application area of the conductive paste (conductive layer 24, 26, or 28) on the electrode layer 16 is changed using conductive paste having a Young's modulus of 60 MPa. As shown in Table 3, when the area exceeds 20 mm², the deterioration of sound pressure exceeds 0.1 dB. Accordingly, the application area on the electrode layer 16 is preferably 20 mm² or less. In a relatively small piezoelectric loudspeaker including the diaphragm 12 having a diameter of about 10 to about 50 mm, the application area of the conductive paste significantly affects the sound quality. The reason for this is as follows: In such a relatively small piezoelectric loudspeaker, the diaphragm 12 has a high rigidity. Therefore, the loudspeaker is less affected by the conductive paste.

TABLE 3

| | Deterioration of sound |
|---|---|
| Resin area | pressure |
| (mm²) | (dB) |
| 0 | 0.00 |
| 1 | 0.00 |
| 2 | −0.01 |
| 5 | −0.03 |
| 10 | −0.05 |
| 15 | −0.07 |
| 20 | −0.09 |
| 25 | −0.34 |

The conductive paste may be paste may be applied by a known method such as printing or spraying. The thickness of the conductive layer 24 (26 or 28 ) is, for example, at least 0.01 mm (10 μm). When the thickness is smaller than 0.01 mm, the resistance becomes excessively high and a stable contact state cannot be achieved. After the application, the conductive paste is cured by a predetermined method, for example, by irradiating ultraviolet rays or by heating. Thus, the piezoelectric loudspeaker 10 wherein the contact state is stable can be produced.

### EXAMPLES

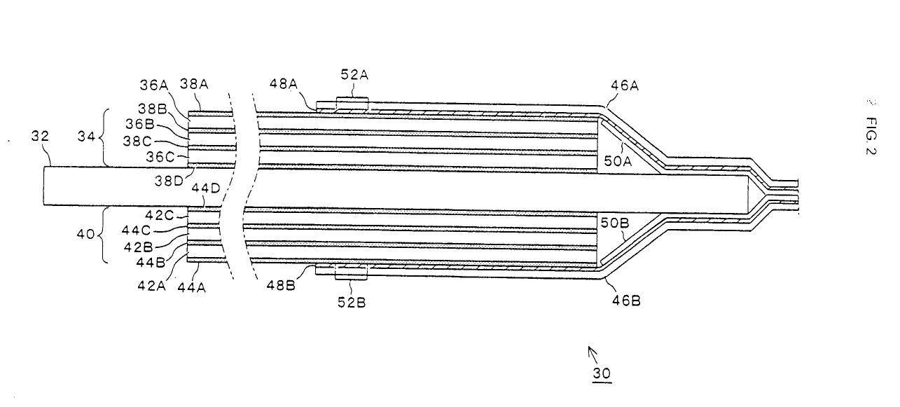

Examples and Comparative examples of the present invention will now be described. FIG. 2 shows a main cross-section of a piezoelectric loudspeaker according to Examples and Comparative examples.

### Example 1

Firstly, Example 1 will now be described. In a piezoelectric loudspeaker 30 of Example 1, piezoelectric elements 34 and 40 having a layered structure were bonded on both faces of a diaphragm 32 to form a bimorph type. Electrode layers 38A and 44A were provided on the surfaces of the piezoelectric elements 34 and 40, respectively. Conductive paths 46A and 46B composed of strip-shaped metal foils were provided on the electrode layers 38A and 44A, respectively. The diaphragm 32 was composed of an iron-nickel alloy and had a diameter of 23 mm and a thickness of 0.03 mm. The piezoelectric element 34 was a layered product formed by alternately laminating three piezoelectric layers 36A to 36C and four electrode layers 38A to 38D. Each of the piezoelectric layers 36A to 36C was composed of lead zirconate titanate and had a diameter of 19 mm and a thickness of 0.018 mm (18 μm). Each of the electrode layers 38A to 38D was composed of a silver-palladium alloy and had a diameter of 18.5 mm and a thickness of 0.001 mm. The electrode layers 38A to 38D were connected to each other by a through-hole. The other piezoelectric element 40 had the same structure as that of the piezoelectric element 34. The piezoelectric element 40 also had a layered structure formed by alternately laminating three piezoelectric layers 42A to 42C and four electrode layers 44A to 44D.

Conductive adhesive layers 48A and 48B were provided on the reverse faces of the conductive paths 46A and 46B, respectively. Each of the conductive paths 46A and 46B was composed of a copper foil and had a thickness of 0.07 mm, a length of 10 mm, and a width of 2 mm. Alternatively, the adhesive layers 48A and 48B may be nonconductive. Furthermore, in order to prevent short-circuiting at a peripheral part of the diaphragm 32 where the metal was exposed, insulating tapes 50A and 50B were applied inside of the conductive paths 46A and 46B, respectively. Polyester-based conductive paste (DW-250H-5 from Toyobo Co., Ltd., Young's modulus: 60 MPa, volume resistivity: 1×10⁻³ Ωcm) including silver as conductive filler was applied on the conductive paths 46A and 46B to form conductive layers 52A and 52B, respectively. Regarding the application shape of the conductive paste, as in the embodiment shown in FIG. 1A, the conductive paste was applied by spraying so as to form two circular shapes having a diameter of 1.0 mm. Each of the area on the conductive path 46A (46B) and the area on the electrode layer 38A (44A) was 0.9 mm². The thickness of the conductive layers 52A and 52B was 0.015 mm.

The resistance between the conductive paths 46A and 46B and the electrode layers 38A and 44A provided on the surfaces of the piezoelectric elements 34 and 40, respectively, of the resultant piezoelectric loudspeaker was measured by a four probe method. Table 4 shows the results. Furthermore, the piezoelectric loudspeaker was installed in a jig so as to fix the periphery thereof. Sine waves with a voltage of 3 Vrms and having a frequency of 1 kHz were then applied to the terminals. The generated sounds were corrected with a microphone and signals amplified with a pre-amplifier were checked with an oscilloscope to observe the presence of waveform distortion. Table 4 shows the results. In Table 4, when waveform distortion was observed, the piezoelectric loudspeaker was determined to be in an unstable contact state, and when such waveform distortion was not observed, the piezoelectric loudspeaker was determined to be in a stable contact state.

### Example 2

The same conductive paste as that in Example 1 was applied on the conductive paths 46A and 46B by printing so as to form rectangular conductive layers 52A and 52B having a dimension of 1.6×4 mm, respectively, as in the embodiment shown in FIG. 1D. Each of the area on the conductive path 46A (46B) and the area on the electrode layer 38A (44A) was controlled to be 3.2 mm². The thickness of the conductive layers 52A and 52B was controlled to be 0.03 mm. The resistance between the conductive paths 46A and 46B and the electrode layers 38A and 44A of the resultant piezoelectric loudspeaker was measured as in Example 1. The presence of waveform distortion of the piezoelectric loudspeaker was also observed as in Example 1.

### Comparative Example 1

A piezoelectric loudspeaker was prepared as in Example 1 except the conductive paste, in other words, except that the conductive layers 52A and 52B were not formed. The measurement of resistance and the observation of the presence of waveform distortion were performed by the methods described above.

### Comparative Example 2

A piezoelectric loudspeaker was prepared as in Example 2 except that the conductive layers 52A and 52B had a Young's modulus of 1,000 MPa, a volume resistivity of 2×10⁻³ Ωcm, and a thickness of 0.02 mm. The measurement of resistance and the observation of the presence of waveform distortion were performed by the methods described above.

### Comparative Example 3

A piezoelectric loudspeaker was prepared as in Example 1 except that the conductive layers 52A and 52B had a Young's modulus of 40 MPa and a volume resistivity of 1×10⁻¹ Ωcm. The measurement of resistance and the observation of the presence of waveform distortion were performed by the methods described above.

### Comparative Example 4

A piezoelectric loudspeaker was prepared as in Example 2 except that the conductive layers 52A and 52B had a thickness of 0.005 mm. The measurement of resistance and the observation of the presence of waveform distortion were performed by the methods described above.

Table 4 shows the physical properties, the application shapes, the application areas, and the thicknesses of the conductive layers 52A and 52B, and in addition, the measured values of the contact resistance between the conductive paths 46A and 46B and the electrode layers 38A and 44A provided on the surfaces of the piezoelectric elements 34 and 40 of the piezoelectric loudspeakers, respectively, and the presence of waveform distortion of the piezoelectric loudspeakers in Examples 1 and 2 and Comparative examples 1 to 4.

TABLE 4

| | Young's | Volume | | Area on | Area on | | Contact | |
|---|---|---|---|---|---|---|---|---|
| | modulus | resistivity | Application | copper foil | electrode | Thickness | resistance | Waveform |
| | (MPa) | (Ω cm) | shape | (mm²) | (mm²) | (mm) | (Ω) | distortion |
| Example 1 | 60 | 1 × 10⁻³ | 1 mm in | 0.9 | 0.9 | 0.015 | 0.11 | Not observed |
| | | | diameter × 2 | | | | | |
| | | | points | | | | | |
| Example 2 | 60 | 1 × 10⁻³ | 1.6 × 4 mm | 3.2 | 3.2 | 0.03 | 0.08 | Not observed |
| Comparative | Without conductive paste | | | | | | 4.22 | Observed |
| example 1 | | | | | | | | (Sounds were |
| | | | | | | | | not generated.) |
| Comparative | 1,000 | 2 × 10⁻³ | 1.6 × 4 mm | 3.2 | 3.2 | 0.02 | 1.86 | Observed |
| example 2 | | | | | | | | (Sounds were |
| | | | | | | | | not generated.) |
| Comparative | 40 | 1 × 10⁻¹ | 1 mm in | 0.9 | 0.9 | 0.015 | 2.09 | Observed |
| example 3 | | | diameter × 2 | | | | | |
| | | | points | | | | | |
| Comparative | 60 | 1 × 10⁻³ | 1.6 × 4 mm | 3.2 | 3.2 | 0.005 | 3.33 | Observed |
| example 4 | | | | | | | | |

Examples 1 and 2 satisfy the following conditions specified in the present invention: The conductive layers 52A and 52B have a Young's modulus of 100 MPa or less and a volume resistivity of 6×10⁻³ Ωcm or less, each of the contact area of the electrode layer 38A (44A) with the conductive layer 52A (52B) and the contact area of the conductive path 46A (46B) with the conductive layer 52A (52B) is at least 0.8 mm², and the thickness of the conductive layers 52A and 52B is at least 0.01 mm (10 μm). Referring to the results in Table 4, regardless of the application shape of the conductive paste, the piezoelectric loudspeakers in Examples 1 and 2 had contact resistances of 0.11 Ω and 0.08 Ω, respectively. In other words, the contact resistance could be maintained within 0.5 Ω and the power loss of signals could be suppressed. Accordingly, a thin piezoelectric loudspeaker having a high efficiency could be achieved. Furthermore, regardless of the application shape, waveform distortion was not observed in Examples 1 and 2. In other words, a stable contact state could be achieved.

In contrast, referring to the results of contact resistance in Comparative examples, the piezoelectric loudspeaker in Comparative example 1, which did not include conductive paste, had a very high contact resistance of 4.22 Ω. In Comparative example 3 for comparing with Example 1, although the Young's modulus satisfied the above condition, the volume resistivity was higher than the above condition. Consequently, the contact resistance in Comparative example 3 was 2.09 Ω. In Comparative example 2 for comparing with Example 2, although the thickness and the volume resistivity satisfied the above conditions, the Young's modulus was larger than the above condition. Consequently, the contact resistance in Comparative example 2 was 1.86 Ω. In Comparative example 4 for comparing with Example 2, although the Young's modulus and the volume resistivity satisfied the above conditions, the thickness was smaller than 0.01 mm. Consequently, the contact resistance in Comparative example 4 was 3.33 Ω. These results showed that piezoelectric loudspeakers prepared under conditions other than the above ranges had a contact resistance of at least 1 Ω, which increased the power loss in this area.

Referring to the results of the presence of waveform distortion in Comparative Examples, in the piezoelectric loudspeaker in Comparative example 1, which did not include conductive paste, waveform distortion was observed, and in addition, sounds themselves were not generated. In all the piezoelectric loudspeakers in Comparative examples 2 to 4 prepared under conditions other than the above ranges by changing the physical properties and the thickness of conductive paste, waveform distortion was observed. This result showed that a satisfactory sound reproducibility could not be achieved. In particular, in the piezoelectric loudspeaker in Comparative example 2 using conductive paste having a high Young's modulus, the conductive paste was broken by vibration and the sounds themselves were not generated.

As described above, in a piezoelectric loudspeaker including a diaphragm and a piezoelectric element including an electrode layer provided on at least one principal surface of the piezoelectric element, a conductive path composed of a strip-shaped metal foil having an adhesive layer provided on the reverse face thereof connects electrode layers to each other or connects the outer electrode layer to an external circuit. In addition, in the piezoelectric loudspeaker, a conductive layer is provided over the surface of the electrode layer and the top face of the conductive path using conductive paste having a low rigidity and a low volume resistivity. This structure keeps the contact resistance low (for example, 0.5 Q or less) without impairing the sound quality and prevents the power loss of signals. Accordingly, a thin piezoelectric loudspeaker having a high efficiency can be provided.

Furthermore, in a piezoelectric loudspeaker including a diaphragm and a piezoelectric element including an electrode layer provided on at least one principal surface of the piezoelectric element, a conductive path composed of a strip-shaped metal foil having an adhesive layer provided on the reverse face thereof connects electrode layers to each other or connects the outer electrode layer to an external circuit. In addition, in the piezoelectric loudspeaker, a conductive layer is provided over the surface of the electrode layer and the top face of the conductive path so as to be connected to the electrode layer at a plurality of points along the edge of the conductive path using conductive paste having a low rigidity and a low volume resistivity. This structure provides the conductive path having a low resistance. Accordingly, even when particles of a piezoelectric material, which become a barrier, are precipitated on the surface of the electrode layer by a simultaneous sintering process using an electrode material with a low cost, the contact resistance is not varied by vibration to provide a stable electrical connection state. Thus, a thin piezoelectric loudspeaker having a satisfactory sound reproducibility can be provided with a low cost.

The present invention includes a plurality of embodiments, which can be variously modified according to the above disclosure. For example, the embodiments include the following:

(1) The materials, the shapes, and the dimensions described in the Examples are examples and can be appropriately changed so as to provide the same operation. For example, the application shapes of the conductive layers 24, 26, 28, 52A, and 52B are examples. The application shape may be appropriately changed within the range of the above conditions (the area and the thickness) so long as the conductive layer is connected to the electrode layer 16 at a plurality of points along the edge of the conductive path. Furthermore, for example, when the piezoelectric loudspeaker is a bimorph type, the shape of a conductive layer formed on an electrode layer of one piezoelectric element may be different from the shape of another conductive layer formed on the other electrode layer of the other piezoelectric element.

(2) The number of the piezoelectric layers and the electrode layers may be changed according to need. In the Examples, three piezoelectric layers are laminated in order to achieve a sufficient driving force. The number of the layers may be further increased so long as the total thickness of the layered product does not exceed 0.1 mm. Also, for example, the connecting structure of the inner electrode layers may be appropriately changed according to need.

(3) Although the adhesive layers 48A and 48B in the Examples are composed of a conductive material, the adhesive layers 48A and 48B may be composed of a nonconductive material.

(4) Examples of the preferable application of the present invention include a loudspeaker of various electronic devices such as cellular phones (including PHS), personal digital assistances (PDA), voice recorders, and personal computers (PC). The present invention may be used for other various applications.

As described above, according to the present invention, the contact resistance can be kept low without impairing the sound quality and the loss of signals can be prevented to achieve a high efficiency. According to the present invention, a stable electrical connection state can be provided. Accordingly, the present invention can be applied to a thin piezoelectric loudspeaker, and in particular, to an ultra-thin piezoelectric loudspeaker having a thickness of 1 mm or less.

As many apparently widely different embodiments of the present invention may be made without departing from the spirit and scope thereof, it is to be understood that the present invention is not limited to the specific embodiments thereof except as defined in the appended claims.

What is claimed is:

1. A piezoelectric loudspeaker comprising:
a piezoelectric element including a piezoelectric material and an electrode layer that is provided on at least one principal surface of the piezoelectric element;
a diaphragm applied on the other principal surface of the piezoelectric element;
a conductive path conductively connecting electrode layers of the piezoelectric element to each other or connecting one of the electrode layers of the piezoelectric element to an external circuit, the conductive path being bonded on the electrode layer and
a conductive layer formed by applying conductive paste, the conductive layer being provided over at least a portion of the surface of the electrode layer and at least a portion of the top face of the conductive path, and the conductive layer having a Young's modulus of 100 MPa or less and a volume resistivity of 6×10⁻³ Ωcm or less.

2. The piezoelectric loudspeaker according to claim 1, wherein each of the contact area of the surface of the electrode layer with the conductive layer and the contact area of the conductive path with the conductive layer is at least 0.8 mm², and wherein the thickness of the conductive layer is at least 0.01 mm.

3. The piezoelectric loudspeaker according to claim 2, wherein the contact area of the surface of the electrode layer with the conductive layer is 20 mm² or less.

4. The piezoelectric loudspeaker according to claim 1, wherein the diaphragm has a diameter of 10 to 50 mm.

5. The piezoelectric loudspeaker according to claim 1, wherein the piezoelectric element is applied on at least one principal surface of the diaphragm.

6. The piezoelectric loudspeaker according to claim 1, wherein the piezoelectric element has a layered structure formed by alternately laminating a plurality of piezoelectric layers and electrode layers.

7. The piezoelectric loudspeaker according to claim 6, wherein the piezoelectric element comprises at least three piezoelectric layers.

8. The piezoelectric loudspeaker of claim 1, wherein said conductive path comprises a strip-shaped metal foil.

9. The piezoelectric loudspeaker of claim 8, wherein said strip-shaped metal foil has conductive adhesive on one side thereof.

10. A piezoelectric loudspeaker comprising:
a piezoelectric element including a piezoelectric material and an electrode layer that is provided on at least one principal surface of the piezoelectric element;
a diaphragm applied on the other principal surface of the piezoelectric element;
a conductive path conductively bonded on the electrode layer in order to connect electrode layers of the piezoelectric element to each other or connect one of the electrode layers of the piezoelectric element to an external circuit; and
a conductive layer formed by applying conductive paste, the conductive layer being provided over at least a portion of the surface of the electrode layer and at least a portion of the top face of the conductive path,
wherein the conductive layer is provided so as to be connected to the electrode layer at a plurality of points along the edge of the conductive path.

11. The piezoelectric loudspeaker according to claim 10, wherein the conductive layer is provided on both sides of the conductive path or across the conductive path.

12. The piezoelectric loudspeaker according to claim 10, wherein the conductive layer has a Young's modulus of 100 MPa or less and a volume resistivity of 6×10⁻³ Ωcm or less.

13. The piezoelectric loudspeaker according to claim 10, wherein each of the contact area of the surface of the electrode layer with the conductive layer and the contact area of the conductive path with the conductive layer is at least 0.8 mm², and wherein the thickness of the conductive layer is at least 0.01 mm.

14. The piezoelectric loudspeaker according to claim 13, wherein the contact area of the surface of the electrode layer with the conductive layer is 20 mm² or less.

15. The piezoelectric loudspeaker according to claim 10, wherein the diaphragm has a diameter of 10 to 50 mm.

16. The piezoelectric loudspeaker according to claim 10, wherein the piezoelectric element is applied on at least one principal surface of the diaphragm.

17. The piezoelectric loudspeaker according to claim 10, wherein the piezoelectric element has a layered structure formed by alternately laminating a plurality of piezoelectric layers and electrode layers.

18. The piezoelectric loudspeaker according to claim 17, wherein the piezoelectric element comprises at least three piezoelectric layers.

19. The piezoelectric loudspeaker of claim 10, wherein said conductive path comprises a strip-shaped metal foil

20. The piezoelectric loudspeaker of claim 19, wherein said strip-shaped metal foil has conductive adhesive on one side thereof.
